(19) United States
(12) Patent Application Publication
(10) Pub. No.: US 2024/0339172 A1
(43) Pub. Date: Oct. 10, 2024

(54) ADAPTIVE BLOCK FAMILY ERROR AVOIDANCE SCAN BASED ON DYNAMIC PAGE ERROR STATISTICS

(71) Applicant: Micron Technology, Inc., Boise, ID (US)

(72) Inventors: Yugang Yu, Folsom, CA (US); Chun Sum Yeung, San Jose, CA (US); Pitamber Shukla, San Jose, CA (US)

(21) Appl. No.: 18/624,720

(22) Filed: Apr. 2, 2024

Related U.S. Application Data
(60) Provisional application No. 63/457,640, filed on Apr. 6, 2023.

(51) Int. Cl. G11C 29/52; G11C 29/02

(52) U.S. Cl. CPC G11C 29/52; G11C 29/022; G11C 29/028

(57) ABSTRACT

Aspects of the present disclosure are directed to a memory sub-system using a block family error avoidance (BFEA) scan to adjust read voltages. Three-level cell (TLC) memory stores three bits per cell. Due to variances in manufacturing and degradation over time, the actual voltages stored in the memory cells deviate from the target voltages. As a result, the comparisons between the read voltages and the stored voltages may generate erroneous results. A BFEA scan may be based on a single wordline and single page type. However, determining a single threshold voltage shift to apply to all read voltages may not compensate for all causes of voltage shifting. Accordingly, a BFEA scan may use multiple wordlines (e.g., one for each page) and determine different voltage offset values for each page. As a result, the accuracy of the read voltage applied is increased and the bit error rate (BER) is reduced.

### PRIORITY APPLICATION

This application claims the benefit of priority to U.S. Provisional Application Ser. No. 63/457,640, filed Apr. 6, 2023, which is incorporated herein by reference in its entirety.

### TECHNICAL FIELD

The present disclosure generally relates to memory sub-systems and, more specifically, to error recovery in memory sub-systems.

BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

Memory cells may store a single bit per cell or multiple bits per cell. For example, triple-level cell (TLC) memory stores three bits per cell. The data may be stored by storing one of eight levels of charge in the cell. The eight voltage levels of a TLC may be referred to as L0-L7, with L0 having the lowest threshold voltage and L7 having the highest threshold voltage.

The data of a TLC may be read by comparing the threshold voltage of the cell to a read level voltage. The 3 bits in TLC cell are called lower page (LP, right-most bit), upper page (UP, center bit) and extra page (XP, left-most bit). For LP read, to determine if the bit is a 0 or a 1, in the cell voltage is compared to two read voltages R1 (between L0 and L1) and R5 (between L4 and L5). Similarly, to determine UP, read voltages R2 (between L1 and L2), R4 (between L3 and L4), and R6 (between L5 and L6) are used. To read XP, read voltages R3 (between L2 and L3) and R7 (between L6 and L7) are used.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system in accordance with some embodiments of the present disclosure.

FIG. 2 shows graphs of count fail byte (CFByte) responses for a memory component, in accordance with some embodiments of the present disclosure.

FIG. 3 is a graph of register rate values for a memory component, in accordance with some embodiments of the present disclosure.

FIG. 4 is a flow diagram of an example method for a block family error avoidance (BFEA) scan, in accordance with some embodiments of the present disclosure.

FIG. 5 is a flow diagram of an example method for a BFEA scan, in accordance with some embodiments of the present disclosure.

FIG. 6 is a flow diagram of an example method for reading data from a memory component using a voltage adjustment determined based on a BFEA scan, in accordance with some embodiments of the present disclosure.

FIG. 7 is a block diagram of an example database schema, suitable for use in storing results of a BFEA scan and determining a voltage adjustment for reading data from a memory component, in accordance with some embodiments of the present disclosure.

FIG. 8 is a block diagram of an example computer system in which embodiments of the present disclosure may operate.

### DETAILED DESCRIPTION

Aspects of the present disclosure are directed to a memory sub-system using a BFEA scan to adjust read level voltages. A memory sub-system is also hereinafter referred to as a “memory system.” An example of a memory sub-system is a storage system, such as a solid-state drive (SSD). In some embodiments, the memory sub-system is a hybrid memory/storage sub-system. In general, a host system can utilize a memory sub-system that includes one or more memory components. The host system can provide data to be stored at the memory sub-system and can request data to be retrieved from the memory sub-system.

The memory sub-system can include multiple memory components that can store data from the host system. Different memory components can include different types of media. Examples of media include, but are not limited to, a cross-point array of non-volatile memory and flash-based memory cells.

Due to variances in manufacturing and degradation over time, the actual threshold voltages stored in the memory cells deviate from the target threshold voltages. As a result, the comparisons between the read voltages and the cell threshold voltages may generate erroneous results. The life of a particular memory system may be extended by detecting the variations in the stored voltages and adjusting the read voltages to compensate.

A BFEA scan may be based on a single wordline and single page type (e.g., the extra page). The threshold voltage shift due to slow charge loss may be most severe at the highest valley (between levels L6 and L7, in a TLC). However, determining a single threshold voltage shift to apply to all read level voltages may not compensate for other causes of voltage shifting that apply to other levels. For example, cross-temperature effects, in which the temperature at which data is written differs from the temperature at which the data is read, may affect other levels differently.

Accordingly, a BFEA scan may use multiple wordlines (e.g., one for each page) and determine different voltage offset values for each page. As a result, the accuracy of the read voltage applied is increased and the bit error rate (BER) is reduced. Thus, the ability to perform a successful read voltage calibration is enhanced, increasing the useful lifetime of a memory device.

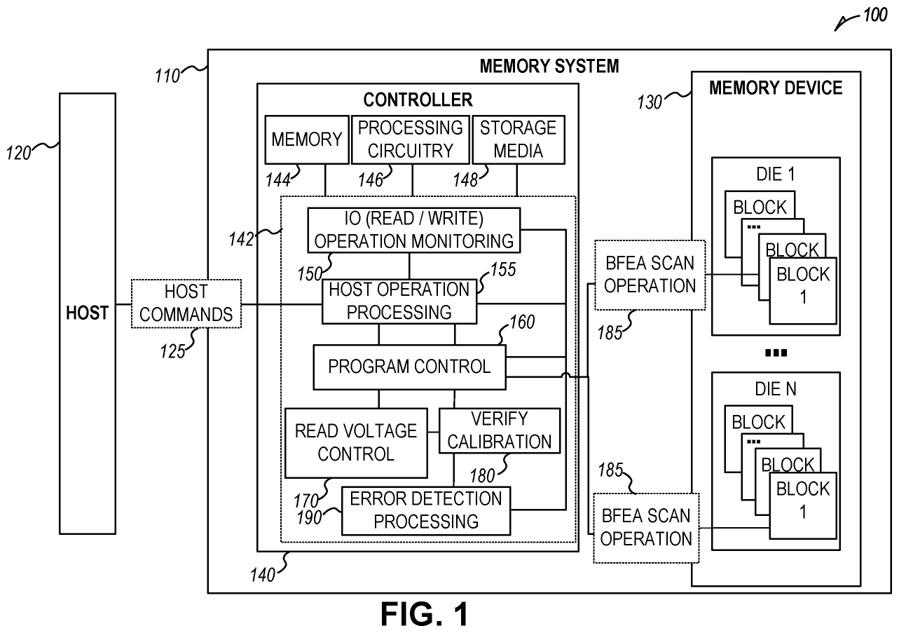

FIG. 1 provides a block diagram of an example system 100 including a memory system 110 (e.g., a SSD storage device, a SD/MMC card, etc.) having a memory controller 140 and a memory device 130. In an example, the functionality of control modules 142 of the memory controller 140 may be implemented in respective modules in a firmware of the memory controller 140. However, it will be understood that various forms of software, firmware, and hardware may be utilized by the controller 140 to implement the control modules 142 (e.g., implement the functionality of program control 160) and the other techniques discussed herein.

As shown, the memory system 110 includes a NAND memory device 130 with multiple dies (dies 1-N), with each die including one or more blocks (blocks 1-N). Each of the one or more blocks may include further divided portions, such as one or more wordlines (not shown) per block; and each of the one or more wordlines may be further comprised of one or more pages (not shown) per wordline, depending on the number of data states that the memory cells of that wordline are configured to store.

Accessing data from the memory device 130 may comprise applying a read voltage to a wordline, wherein the voltage applied to the wordline is different than the signaling voltage used to indicate that the voltage should be applied. A voltage level shifter may be used to convert the signaling voltage in a first power domain to the read voltage in a second power domain. By using the transition time reduction techniques and circuits discussed herein, the transition time for applying or ceasing to apply the read voltage may be reduced, improving performance of the memory device 130 by reducing power consumption, increasing operating frequency, or both.

In an example, the blocks of memory cells of the memory device 130 include groups of at least one of: single-level cell (SLC), multi-layer cell (MLC), triple-layer cell (TLC), or quad-layer cell (QLC) NAND memory cells. Also, in an example, the memory device 130 is arranged into a stack of three-dimensional (3D) NAND dies. These configurations and further detailed components of the memory device 130 are not illustrated in FIG. 1 for simplicity. However, the memory device 130 may incorporate these or any of the features described above with reference to features of 3D NAND architecture devices or other forms of NAND storage devices.

In 3D architecture semiconductor memory technology, vertical structures are stacked, increasing the number of tiers, physical pages, and accordingly, the density of a memory device (e.g., a storage device). In an example, the memory system 110 can be a discrete memory or storage device component of the host device 120. In other examples, the memory system 110 can be a portion of an integrated circuit (e.g., system on a chip (SOC), etc.), stacked or otherwise included with one or more other components of the host device 120.

Each flash memory cell in a NAND architecture semiconductor memory array may be programmed to two or more programmed states. For example, an SLC may represent one of two programmed states (e.g., 1 or 0), representing one bit of data. Flash memory cells may also represent more than two programmed states, allowing the manufacture of higher density memories without increasing the number of memory cells, as each cell may represent more than one binary digit (e.g., more than one bit). Such cells may be referred to as multi-state memory cells, multi-digit cells, or multi-level cells (MLCs). In certain examples, MLC may refer to a memory cell that may store two bits of data per cell (e.g., one of four programmed states), TLC may refer to a memory cell that may store three bits of data per cell (e.g., one of eight programmed states), and a QLC may store four bits of data per cell. MLC is used herein in its broader context, to refer to any memory cell(s) that may store more than one bit of data per cell (i.e., that may represent more than two programmed states; thus, the term MLC is used herein in the broader context, to be generic to memory cells storing 2, 3, 4, or more bits of data per cell).

The memory system 110 is shown as being operably coupled to a host device 120 via a controller 140 of the memory device. The controller 140 is adapted to receive and process host IO commands 125, such as read commands, write commands, erase commands, and the like, to read, write, erase, and manage data stored within the memory device 130. In other examples, the memory controller 140 may be physically separate from an individual memory device, and may receive and process commands for one or more individual memory devices. A variety of other components for the memory system 110 (such as a memory manager, and other circuitry or operational components) and the controller 140 are also not depicted for simplicity.

The controller 140 is depicted as including a memory 144 (e.g., volatile memory), processing circuitry 146 (e.g., a microprocessor), and a storage media 148 (e.g., non-volatile memory), used for executing instructions (e.g., instructions hosted by the storage media 148, loaded into memory 144, and executed by the processing circuitry 146) to implement the control modules 142 for management and use of the memory device 130. The functionality provided by the control modules 142 may include, but is not limited to: IO operation monitoring 150 (e.g., to monitor read and write IO operations, originating from host commands); host operation processing 155 (e.g., to interpret and process the host IO commands 125, and to issue further commands to the NAND memory device 130 to perform respective read, write, erase, or other host-initiated operations); program control 160 (e.g., to control the timing, criteria, conditions, and parameters of respective BFEA scan operations 185 on the memory device 130); read voltage control 170 (e.g., to establish, set, and utilize a program voltage level to read a particular portion of the memory device 130);

verify calibration 180 (e.g., to operate a calibration procedure to identify a new programmed voltage level of a particular portion or portions of the memory device 130); and error detection processing 190 (e.g., to identify and correct errors from data obtained in read operations, to identify one or more raw bit error rates (RBER(s)) for a particular read operation or set of operations, etc.).

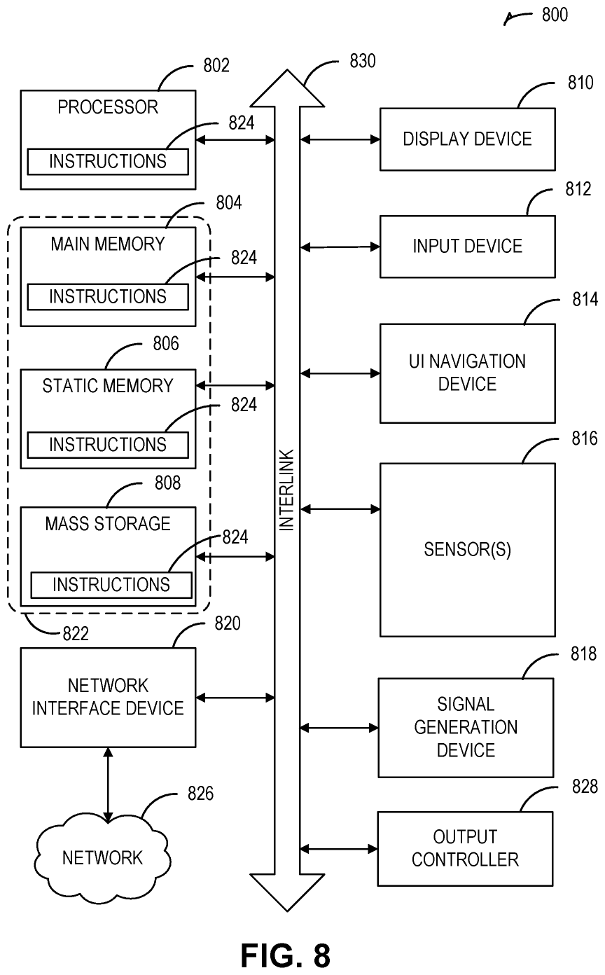

One or more communication interfaces can be used to transfer the host IO commands 125 between the memory system 110 and one or more other components of the host device 120, such as a Serial Advanced Technology Attachment (SATA) interface, a Peripheral Component Interconnect Express (PCIe) interface, a Universal Serial Bus (USB) interface, a Universal Flash Storage (UFS) interface, an eMMCTM interface, or one or more other connectors or interfaces. The host device 120 can include a host system, an electronic device, a processor, a memory card reader, or one or more other electronic devices external to the memory system 110. In some examples, the host device 120 may be a machine having some portion, or all, of the components discussed in reference to the machine 800 of FIG. 8.

In an example, the host operation processing 155 is used to interpret and process the host IO commands 125 (e.g., read and write commands) and initiate accompanying commands in the controller 140 and the memory device 130 to accomplish the host IO commands 125. Further, the host operation processing 155 may coordinate timing, conditions, and parameters of the program control 160 in response to the host IO commands 125, IO operation monitoring 150, and error detection processing 190.

The IO operation monitoring 150 operates, in some example embodiments, to track reads and writes to the memory device 130 initiated by host IO commands. The IO operation monitoring 150 also operates to track accompanying IO operations and states, such as a host IO active or inactive state (e.g., where an active state corresponds to the state of the controller 140 and memory device 130 actively performing read or write IO operations initiated from the host device 120, and where an inactive state corresponds to an absence of performing such IO operations initiated from the host device 120). The IO operation monitoring 150 may also monitor voltage level and read error rates occurring with the IO operations initiated from the host device 120, in connection with determining parameters for the program control 160 as discussed herein.

The program control 160 can include, among other things, circuitry or components (hardware and/or software) configured to control memory operations associated with writing data to, reading data from, or erasing one or more memory cells of the memory device 130 coupled to the memory controller 140. In an example, the program control 160 operates to identify parameters in the memory device 130 and controller 140 for scheduling and conducting a BFEA scan operation 185, such as based on the IO conditions (e.g., indicated by the IO operation monitoring 150) or error conditions (e.g., indicated by the error detection processing 190). The program control 160 further operates to initiate and perform the BFEA scan operation 185 based on these or other parameters, through synchronous or asynchronous event processing.

The read voltage control 170, in some example embodiments, is used to establish, change, and provide a voltage value used to read a particular area of memory (such as a respective block in the memory device 130). For example, the read voltage control 170 may implement various positive or negative offsets in order to read respective memory cells and memory locations (e.g., pages, blocks, dies) including the respective memory cells. A voltage level shifter may be used to transition control signals from a first power domain to control signals in a second power domain. The operating voltage of the second power domain may be controlled by the read voltage control 170. For example, a common ground may be used in the two power domains, a fixed voltage source used as the operating voltage of the first power domain, and the output of a voltage source, configured by the read voltage control 170, used as the operating voltage of the second power domain.

In an example, the verify calibration 180 is used to establish (e.g., change, update, reset, etc.) whether or not a verify operation should be performed after a program operation. The verify calibration 180 may be implemented based on a number or percentage of bits in the NAND memory device 130 that were successfully programmed at a lower voltage level.

The error detection processing 190, in some example embodiments, may detect a recoverable error condition (e.g., a RBER value or an RBER trend), an unrecoverable error condition, or other measurements or error conditions for a memory cell, a group of cells, or larger areas of the memory array (e.g., averages or samples from a block, group of blocks, die, group of dies, etc.).

Additionally, the sampling and read operations that are performed in a read scan by the program control 160 may allow configuration, such as from a specification (e.g., a determined setting or calculation) of: a size of data (e.g., data corresponding to a page, block, group of blocks, die) that is programmed; a number of pages in total that are programmed; a number of pages within a block that are programmed; whether certain cells, pages, blocks, dies, or certain types of such cells, pages, blocks, dies are or are not programmed; and the like. Likewise, the program control 160 may control or allow configuration of the number of program cycles that are performed before the first verify cycle, the number of program cycles that are performed between verify cycles, the number of bits to be successfully programmed at each level before next-level verification begins, or any suitable combination thereof.

In addition to the techniques discussed herein, other types of maintenance operations may be implemented by the control modules 142 in the controller 140. Such operations may include garbage collection or reclamation, wear leveling, block management, and other forms of background activities performed upon the memory device 130. Such background activities may be triggered during an idle state detected by the IO operation monitoring 150, such as immediately following or concurrently with a read scan operation.

The program control 160 can include an error correction code (ECC) component, which can include, among other things, an ECC engine or other circuitry configured to detect or correct errors associated with writing data to or reading data from one or more memory cells of the memory device 130 coupled to the memory controller 140. The memory controller 140 can be configured to actively detect and recover from error occurrences (e.g., bit errors, operation errors, etc.) associated with various operations or storage of data, while maintaining integrity of the data transferred between the host device 120 and the memory system 110, or maintaining integrity of stored data (e.g., using redundant RAID storage, etc.), and can remove (e.g., retire) failing memory resources (e.g., memory cells, memory arrays, pages, blocks, etc.) to prevent future errors.

The memory device 130 can include several memory cells arranged in, for example, a number of devices, planes, sub-blocks, blocks, or pages. As one example, a 48 GB TLC NAND memory device can include 18,592 bytes (B) of data per page (16,384+2208 bytes), 1536 pages per block, 548 blocks per plane, and 4 or more planes per device. As another example, a 32 GB MLC memory device (storing two bits of data per cell (i.e., 4 programmable states)) can include 18,592 bytes (B) of data per page (16,384+2208 bytes), 1024 pages per block, 548 blocks per plane, and 4 planes per device, but with half the required write time and twice the program/erase (P/E) cycles as a corresponding TLC memory device. Other examples can include other numbers or arrangements. In some examples, a memory device, or a portion thereof, may be selectively operated in SLC mode, or in a desired MLC mode (such as TLC, QLC, etc.).

In operation, data is typically written to or read from the memory system 110 in pages, and erased in blocks. However, one or more memory operations (e.g., read, write, erase, etc.) can be performed on larger or smaller groups of memory cells, as desired. The data transfer size of a NAND memory system 110 is typically referred to as a page, whereas the data transfer size of a host is typically referred to as a sector.

Although a page of data can include a number of bytes of user data (e.g., a data payload including a number of sectors of data) and its corresponding metadata, the size of the page often refers only to the number of bytes used to store the user data. As an example, a page of data having a page size of 4 KB may include 4 KB of user data (e.g., 8 sectors assuming a sector size of 512 B) as well as a number of bytes (e.g., 32 B, 54 B, 224 B, etc.) of metadata corresponding to the user data, such as integrity data (e.g., error detecting or correcting code data), address data (e.g., logical address data, etc.), or other metadata associated with the user data.

Different types of memory cells or memory devices 130 can provide for different page sizes, or may require different amounts of metadata associated therewith. For example, different memory device types may have different bit error rates, which can lead to different amounts of metadata necessary to ensure integrity of the page of data (e.g., a memory device with a higher bit error rate may require more bytes of error correction code data than a memory device with a lower bit error rate). As an example, a multi-level cell (MLC) NAND flash device may have a higher bit error rate than a corresponding single-level cell (SLC) NAND flash device. As such, the MLC device may require more metadata bytes for error data than the corresponding SLC device.

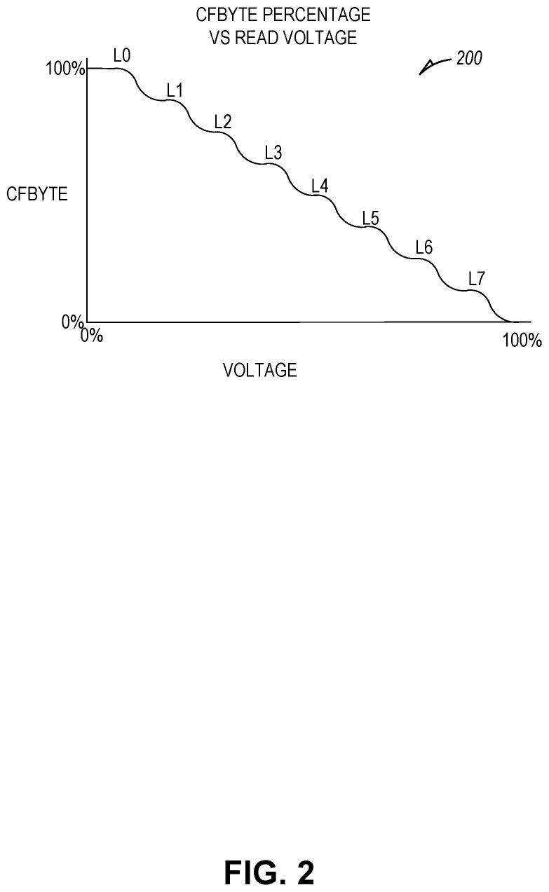

FIG. 2 shows graph 200 of CFByte responses for a memory component, in accordance with some embodiments of the present disclosure. The graph 200 shows the CFByte read percentage as a function of read voltage percentage over the entire read voltage range for a memory device. The graph 200 shows that at a minimum read voltage, all memory cells store voltages above the read voltage and thus CFByte is at 100% of the memory cells. At a maximum read voltage, all memory cells store voltages below the read voltage and thus CFByte is at 0% of the memory cells. As the read voltage increases from the minimum to the maximum, the CFByte percentage decreases. The CFByte value changes quickly as a function of read voltage when the read voltage is near the target voltage for a level, as many memory cells are storing voltages slightly above or below the target voltage. The CFByte value changes slowly as a function of read voltage when the read voltage is in between two adjacent distributions, as few memory cells are storing voltages for which it is difficult to determine which target voltage was intended. Thus, the graph 200 has a roughly stair-step shape, with the center of the flatter portions indicating the read voltages that best distinguish between adjacent target voltages.

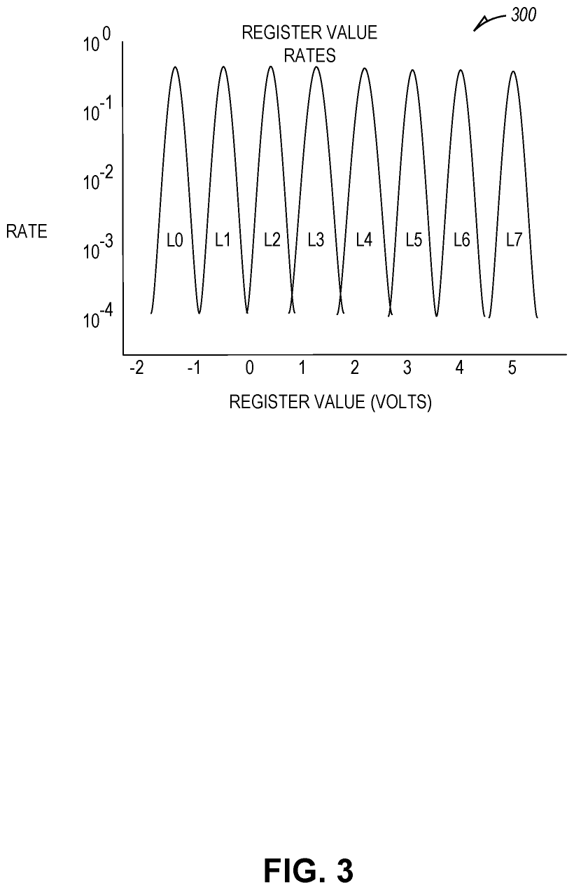

FIG. 3 is a graph 300 of register rate values for a memory component, in accordance with some embodiments of the present disclosure. As can be seen in the graph 300, the threshold voltage distribution for data peaks near the target voltage value for each of L0-L7. However, the voltages are not entirely at the target voltage. Some of the voltage distributions overlap, such as the L2 and L3 distributions. As a result, regardless of the read voltage used, some L2 values will be read as L3 values or vice versa. By using read voltages located at the positions of minimum overlap, the number of read errors is minimized.

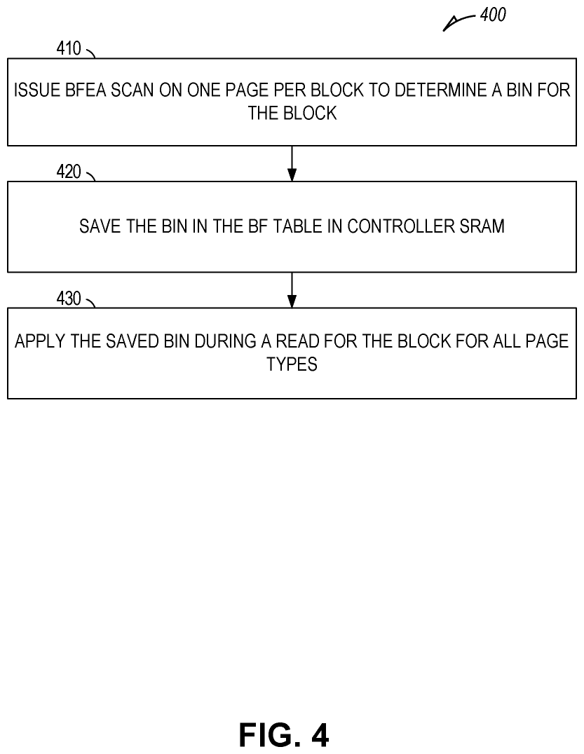

FIG. 4 is a flow diagram of an example method 400 for a BFEA scan, in accordance with some embodiments of the present disclosure. The method 400 includes operation 410, 420, and 430. By way of example and not limitation, the method 400 is described as being performed by the read voltage control 170 of FIG. 1 in conjunction with the memory device 130 of FIG. 1.

In operation 410, the read voltage control 170 issues a BFEA scan (e.g., the BFEA scan operation 185 of FIG. 1) on one page (e.g., lower page, upper page, or extra page) per block to determine a bin for the block. The “bin” refers to a read level voltage shift range for data read at all read voltage levels determined by the program-to-read delay time and the slow charge loss (SCL) effect during the delay. For example, bin 0 may refer to little delay between program and read and minimum SCL hence no read level shift. Bin 1 may refer to a small read level offset. Bin 2 may refer to a higher read level shift than bin 1. The number of bins and their corresponding ranges may vary from implementation to implementation.

The bin determined in operation 410 may be based on the RBER for the extra page when using one or more bins. For example, during a BFEA scan, the system may check the XP RBER value of pre-defined scanned wordlines while iterating through the bins. Once the read with any bin is having XP RBER lower than a predetermined the limit (which is set to be low to select the bin with best performance), the bin for the block has been determined. The bin determined in operation 410 is saved in a block family (“BF”) table in a controller static random access memory (“SRAM”) (operation 420). For example, the memory 144 of FIG. 1 may be implemented as an SRAM. The BF table may contain a bin for each block in the memory device 130.

In operation 430, the read voltage control 170 applies a voltage offset based on the saved bin during reads for the block, for all page types. For example, no voltage offset may be applied to a nominal read voltage for blocks in bin 0, a voltage offset of −10 mV may be applied to a certain read level of blocks in bin 1, and a voltage offset of −20 mV may be applied to a certain read level of blocks in bin 2. The page types may include upper page, lower page, and extra page. Thus, a voltage offset determined by a BFEA scan on a single page of a block is applied to all pages of the block.

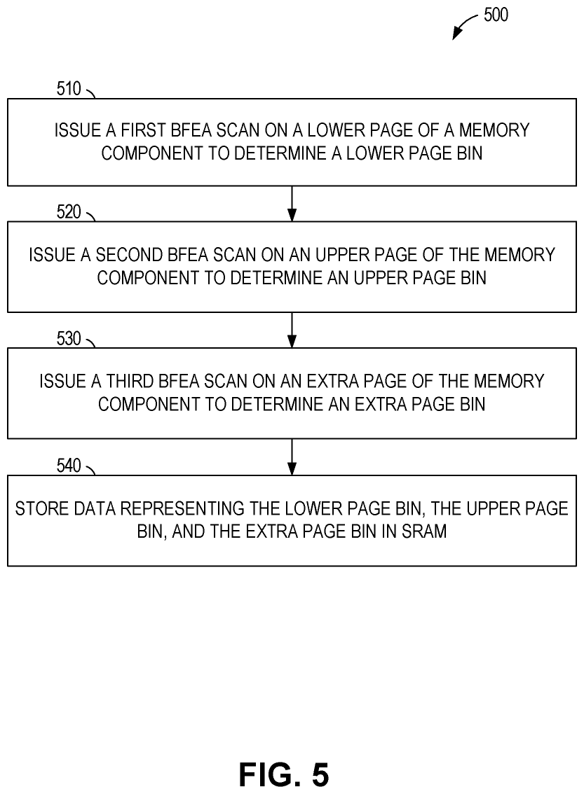

FIG. 5 is a flow diagram of an example method 500 for a BFEA scan, in accordance with some embodiments of the present disclosure. The method 500 includes operation 510, 520, 530, and 540. By way of example and not limitation, the method 500 is described as being performed by the read voltage control 170 of FIG. 1 in conjunction with the memory device 130 of FIG. 1. In some example embodiments, the method 500 is automatically performed periodically by the read voltage control 170. For example, the method 500 may be performed daily, hourly, weekly, or monthly.

In operation 510, the read voltage control 170 issues a first BFEA scan (e.g., the BFEA scan operation 185 of FIG. 1) on a lower page of a memory component (e.g., a block) to determine a lower page bin. The first BFEA scan of the lower page of the memory component scans at R1 and R5 of the TLCs, in some example embodiments.

The read voltage control 170 issues a second BFEA scan on an upper page of the memory component to determine a upper page bin (operation 520). The second BFEA scan of the upper page of the memory component scans at R2, R4, and R6 of the TLCs, in some example embodiments.

An extra page bin is determined from a third BFEA scan on an extra page of the memory component (operation 530). The third BFEA scan of the extra page of the memory component scans at R1 and R5 of the TLCs, in some example embodiments.

The bins determined in operations 510-530 may be based on the RBER for the corresponding page when using one or more bins. For example, during the first BFEA scan, the system may check the LP RBER value of pre-defined scanned wordlines while iterating through the bins. Once the read with any bin is having LP RBER lower than a predetermined the limit (which is set to be low to select the bin with best performance), the LP bin for the block has been determined.

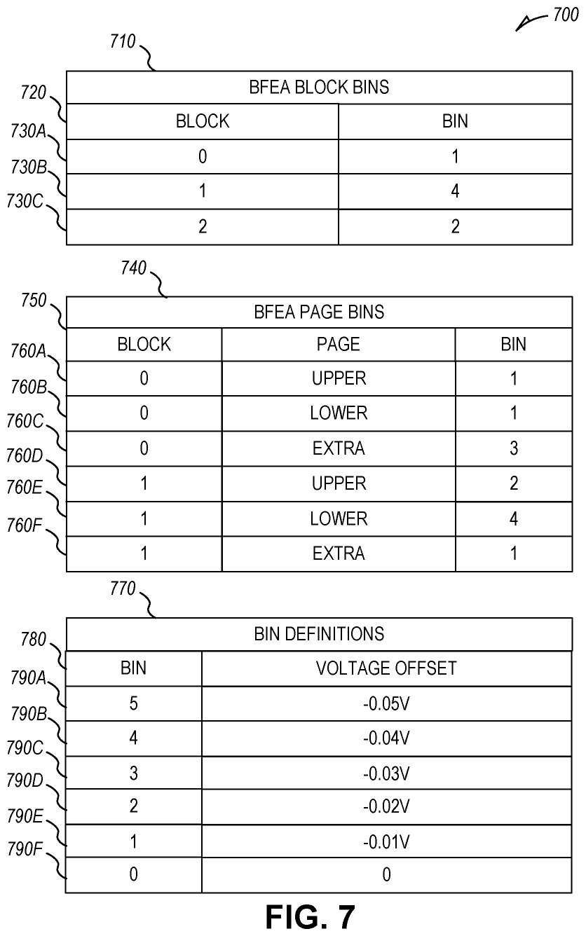

In operation 540, the data representing the lower page bin, the upper page bin, and the extra page bin are stored in an SRAM of the memory controller 140 of FIG. 1. For example, the data may be stored in the BFEA page bins table 740 of FIG. 7. Thereafter, reads for each page of the memory component may be adjusted according to the bin for the corresponding page. Thus, by comparison with a system implementing the method 400, a system implementing the method 500 stores three times as many bin values but is enabled to apply a page-specific voltage adjustment rather than applying a single voltage adjustment for all pages.

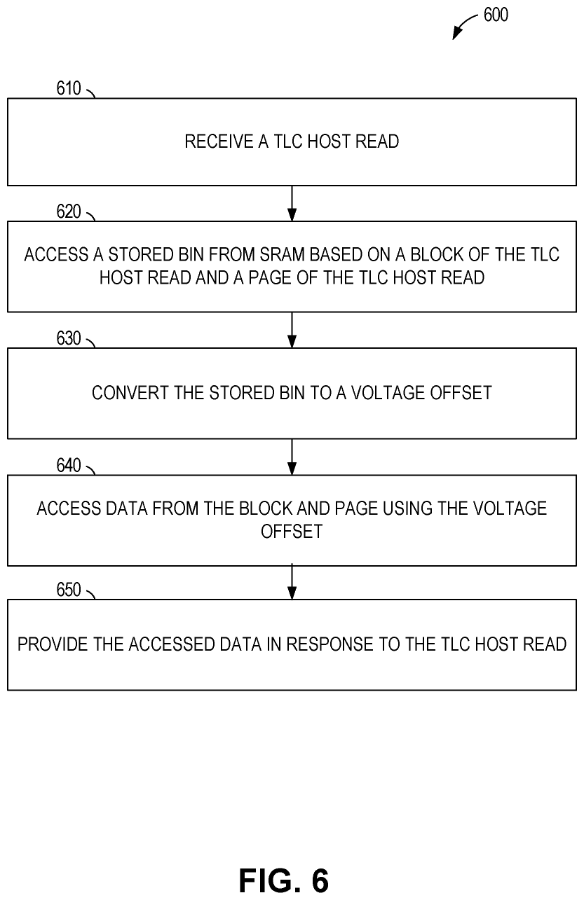

FIG. 6 is a flow diagram of an example method 600 for reading data from a memory component using a voltage adjustment determined based on a BFEA scan, in accordance with some embodiments of the present disclosure. The method 600 includes operations 610, 620, 630, 640, and 650. By way of example and not limitation, the method 600 is described as being performed by the host operation processing 155 and the read voltage control 170 of FIG. 1, in conjunction with the memory device 130 of FIG. 1.

In operation 610, the host operation processing 155 of the controller 140 receives a TLC host read. The TLC host read may request data from a page of a block of memory in the memory device 130.

The read voltage control 170 accesses a stored bin from SRAM based on a block of the TLC host read and a page of the TLC host read (operation 620). For example, the SRAM may store a BF table with a bin value for each page of each block of the memory device 130. The stored bin (e.g., bin 1) is converted to a voltage offset (e.g., −10 mV), in operation 630. The conversion may be performed by using the bin to select a voltage offset from a database table. Alternatively, the conversion may be performed by applying mathematical operations to the bin value.

In operation 640, the host operation processing 155 accesses data from the block and page using the voltage offset. Thus, different voltage offsets may be applied to different pages of the same block and different voltage offsets may be applied to the same page of different blocks. The nominal read level voltage for each page may also be different. For example, if the operating range of the TLC memory is 1.0V, the read level voltage for the extra page may be 0.5V, the read level voltage for the upper page may be 0.25V, and the read level voltage for the lower page may be 0.125V. Thus, reading each page may include determining the default read level voltage for the page, determining a bin for the page, determining a voltage adjustment based on the bin, modifying the read level voltage by applying the voltage adjustment, and reading the page using the modified read voltage.

The host operation processing 155 provides the accessed data to the host in response to the TLC host read (operation 650). In some example embodiments, the TLC host read reads multiple pages (e.g., the lower page, the upper page, and the extra page). In such cases, operations 620-640 may be repeated for each page. The data for all read pages may be provided at once in a single operation 650.

FIG. 7 is a block diagram of an example database schema 700, suitable for use in storing results of a BFEA scan and determining a voltage adjustment for reading data from a memory component, in accordance with some embodiments of the present disclosure. The database schema 700 includes the BFEA block bins table 710, the BFEA page bins table 740, and the bin definitions table 770. The BFEA block bins table 710 includes rows 730A, 730B, and 730C of a format 720. The BFEA page bins table 740 includes rows 760A, 760B, 760C, 760D, 760E, and 760F of a format 750. The bin definitions table 770 includes rows 790A, 790B, 790C, 790D, 790E, and 790F of a format 780.

The BFEA block bins table 710 may be used in conjunction with the method 400 of FIG. 4. Each of the rows 730A-730C stores a bin for a block. Each block has at most one corresponding row in the BFEA block bins table 710. The bin for a block may be determined by performing a BF scan for a single page of the block and is applied to all pages of the block. The voltage offset to be applied when reading data from the block may be determined by cross-referencing the bin to the bin definitions table 770. For example, block 0 is in bin 1 (according to the row 730A) and the voltage offset to be applied when reading blocks in bin 1 is −0.01V (according to the row 790E of the bin definitions table 770).

The BFEA page bins table 740 may be used in conjunction with the method 500 of FIG. 5 and the method 600 of FIG. 6. Each of the rows 760A-760F stores a bin for a page of a block. Thus, each block may have multiple rows, one for each page. The bin for each page is determined by performing a BF scan for the page of the block and storing the result in the BFEA page bins table 740. When performing a read, the voltage offset for the particular page of the block being read is determined by cross-referencing the bin to the bin definitions table 770. For example, the extra page of block 0 is in bin 3 (according to the row 760C) and the voltage offset to be applied when reading the extra page of block 0 is −0.03V (according to the row 790C of the bin definitions table 770).

As discussed above, the bin definitions table 770 may be used to identify the read voltage offset to be applied when reading data from a page or block in a particular bin. Additionally, the bin definitions table 770 may be used during the BF scan to determine the bin for a particular block or page. For example, the bin may be determined by an amount of time that has elapsed since the block or page was written. After the scan, the identified bin may be stored in conjunction with the scanned block or page in the BFEA block bins table 710 or the BFEA page bins table 740.

Example 1 is a memory system comprising: a memory component comprising a plurality of pages; and a processing device programmed to perform operations comprising: issuing a first block family error avoidance (BFEA) scan on a lower page of the memory component to determine a lower page bin; issuing a second BFEA scan on an upper page of the memory component to determine an upper page bin; and issuing a third BFEA scan on an extra page of the memory component to determine an extra page bin.

In Example 2, the subject matter of Example 1, wherein the operations further comprise: storing data representing the lower page bin, the upper page bin, and the extra page bin in static random-access memory (SRAM).

In Example 3, the subject matter of Example 2, wherein the operations further comprise: in response to a read request from a host: accessing the SRAM to determine the lower page bin, the upper page bin, and the extra page bin; determining a lower page read offset voltage based on the lower page bin; determining an upper page read offset voltage based on the upper page bin; determining an extra page read offset voltage based on the extra page bin; modifying a lower page read voltage using the lower page read voltage offset to generate a modified lower page read voltage; modifying an upper page read voltage using the upper page read voltage offset to generate a modified upper page read voltage; modifying an extra page read voltage using the extra page read voltage offset to generate a modified extra page read voltage; using the modified page read voltages to read lower page data, upper page data, and extra page data from the memory component; and providing the read lower page data, the upper page data, and the extra page data to the host.

In Example 4, the subject matter of Examples 1-3, wherein the operations further comprise: periodically repeating the first BFEA scan, the second

BFEA scan, and the third BFEA scan.

In Example 5, the subject matter of Examples 1-4, wherein the first BFEA scan of the lower page of the memory component scans at R1 and R5 of triple-level cell (TLC) memory cells.

In Example 6, the subject matter of Examples 1-5, wherein the second BFEA scan of the upper page of the memory component scans at R2, R4, and R6 of triple-level cell (TLC) memory cells.

In Example 7, the subject matter of Examples 1-6, wherein the third BFEA scan of the extra page of the memory component scans at R3 and R7 of triple-level cell (TLC) memory cells.

Example 8 is a method comprising: issuing, by a processing device, a first block family error avoidance (BFEA) scan on a lower page of a memory component comprising a plurality of memory cells to determine a lower page bin; issuing, by the processing device, a second BFEA scan on an upper page of the memory component to determine an upper page bin; and issuing, by the processing device, a third BFEA scan on an extra page of the memory component to determine an extra page bin.

In Example 9, the subject matter of Example 8 includes storing data representing the lower page bin, the upper page bin, and the extra page bin in static random-access memory (SRAM).

In Example 10, the subject matter of Example 9 includes, in response to a read request from a host: accessing the SRAM to determine the lower page bin, the upper page bin, and the extra page bin; determining a lower page read offset voltage based on the lower page bin; determining an upper page read offset voltage based on the upper page bin; determining an extra page read offset voltage based on the extra page bin; modifying a lower page read voltage using the lower page read voltage offset to generate a modified lower page read voltage; modifying an upper page read voltage using the upper page read voltage offset to generate a modified upper page read voltage; modifying an extra page read voltage using the extra page read voltage offset to generate a modified extra page read voltage; using the modified page read voltages to read lower page data, upper page data, and extra page data from the memory component; and providing the read lower page data, the upper page data, and the extra page data to the host.

In Example 11, the subject matter of Examples 8-10 includes periodically repeating the first BFEA scan, the second BFEA scan, and the third BFEA scan.

In Example 12, the subject matter of Examples 8-11, wherein the first BFEA scan of the lower page of the memory component scans at RI and R5 of triple-level cell (TLC) memory cells.

In Example 13, the subject matter of Examples 8-12, wherein the second BFEA scan of the upper page of the memory component scans at R2, R4, and R6 of triple-level cell (TLC) memory cells.

In Example 14, the subject matter of Examples 8-13, wherein the third BFEA scan of the extra page of the memory component scans at R3 and R7 of triple-level cell (TLC) memory cells.

Example 15 is a non-transitory machine-readable storage medium comprising instructions that, when executed by a processing device, cause the processing device to perform operations comprising: issuing a first block family error avoidance (BFEA) scan on a lower page of a memory component comprising a plurality of memory cells to determine a lower page bin; issuing a second BFEA scan on an upper page of the memory component to determine an upper page bin; and issuing a third BFEA scan on an extra page of the memory component to determine an extra page bin.

In Example 16, the subject matter of Example 15, wherein the operations further comprise: storing data representing the lower page bin, the upper page bin, and the extra page bin in static random-access memory (SRAM).

In Example 17, the subject matter of Example 16, wherein the operations further comprise: in response to a read request from a host: accessing the SRAM to determine the lower page bin, the upper page bin, and the extra page bin; determining a lower page read offset voltage based on the lower page bin;

determining an upper page read offset voltage based on the upper page bin; determining an extra page read offset voltage based on the extra page bin; modifying a lower page read voltage using the lower page read voltage offset to generate a modified lower page read voltage; modifying an upper page read voltage using the upper page read voltage offset to generate a modified upper page read voltage; modifying an extra page read voltage using the extra page read voltage offset to generate a modified extra page read voltage; using the modified page read voltages to read lower page data, upper page data, and extra page data from the memory component; and providing the read lower page data, the upper page data, and the extra page data to the host.

In Example 18, the subject matter of Examples 15-17, wherein the operations further comprise: periodically repeating the first BFEA scan, the second BFEA scan, and the third BFEA scan.

In Example 19, the subject matter of Examples 15-18, wherein the first BFEA scan of the lower page of the memory component scans at R1 and R5 of triple-level cell (TLC) memory cells.

In Example 20, the subject matter of Examples 15-19, wherein the second BFEA scan of the upper page of the memory component scans at R2, R4, and R6 of triple-level cell (TLC) memory cells.

In Example 21, the subject matter of Examples 15-20, wherein the third BFEA scan of the extra page of the memory component scans at R3 and R7 of triple-level cell (TLC) memory cells.

Example 22 is at least one machine-readable medium including instructions that, when executed by processing circuitry, cause the processing circuitry to perform operations to implement any of Examples 1-21.

Example 23 is an apparatus comprising means to implement any of Examples 1-21.

Example 24 is a system to implement any of Examples 1-21.

Example 25 is a method to implement any of Examples 1-21.

FIG. 8 illustrates an example machine of a machine 800 within which a set of instructions can be executed for causing the machine to perform any one or more of the methodologies discussed herein. In some embodiments, the machine 800 can correspond to a host system that includes, is coupled to, or utilizes a memory sub-system (e.g., the memory sub-system 100 of FIG. 1) or can be used to perform the operations of a controller (e.g., to execute an operating system to execute instructions 824 for performing BF scans and adjusting read voltages based on BF bins). In an example, the controller can include memory to store offset voltage adjustments for memory components. The instructions 824 may include, for example, instructions 824 and/or logic described herein. In alternative embodiments, the machine can be connected (e.g., networked) to other machines in a local area network (LAN), an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

FIG. 8 illustrates a block diagram of an example machine 800 with which, in which, or by which any one or more of the techniques (e.g., methodologies) discussed herein can be implemented. Examples, as described herein, can include, or can operate by, logic or a number of components, or mechanisms in the machine 800. Circuitry (e.g., processing circuitry) is a collection of circuits implemented in tangible entities of the machine 800 that include hardware (e.g., simple circuits, gates, logic, etc.). Circuitry membership can be flexible over time. Circuitries include members that can, alone or in combination, perform specified operations when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time. Additional examples of these components with respect to the machine 800.

In alternative embodiments, the machine 800 can operate as a standalone device or can be connected (e.g., networked) to other machines. In a networked deployment, the machine 800 can operate in the capacity of a server machine, a client machine, or both in server-client network environments. In an example, the machine 800 can act as a peer machine in peer-to-peer (P2P) (or other distributed) network environment. The machine 800 can be a PC, a tablet PC, a STB, a PDA, a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 800 (e.g., computer system) can include a hardware processor 802 (e.g., a central processing unit (CPU), a graphics processing unit (GPU), a hardware processor core, or any combination thereof), a main memory 804, a static memory 806 (e.g., memory or storage for firmware, microcode, a basic-input-output (BIOS), unified extensible firmware interface (UEFI), etc.), and mass storage device 808 (e.g., hard drives, tape drives, flash storage, or other block devices) some or all of which can communicate with each other via an interlink 830 (e.g., bus). The machine 800 can further include a display device 810, an alphanumeric input device 812 (e.g., a keyboard), and a user interface (UI) navigation device 814 (e.g., a mouse). In an example, the display device 810, the input device 812, and the UI navigation device 814 can be a touch screen display. The machine 800 can additionally include a signal generation device 818 (e.g., a speaker), a network interface device 820, and one or more sensor(s) 816, such as a global positioning system (GPS) sensor, compass, accelerometer, or other sensor. The machine 800 can include an output controller 828, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 802, the main memory 804, the static memory 806, or the mass storage device 808 can be, or include, a machine-readable media 822 on which is stored one or more sets of data structures or instructions 824 (e.g., software) embodying or used by any one or more of the techniques or functions described herein. The instructions 824 can also reside, completely or at least partially, within any of registers of the hardware processor 802, the main memory 804, the static memory 806, or the mass storage device 808 during execution thereof by the machine 800. In an example, one or any combination of the hardware processor 802, the main memory 804, the static memory 806, or the mass storage device 808 can constitute the machine-readable media 822. While the machine-readable media 822 is illustrated as a single medium, the term “machine-readable medium” can include a single medium or multiple media (e.g., a centralized or distributed database, or associated caches and servers) configured to store the one or more instructions 824.

The term “machine-readable medium” can include any medium that is capable of storing, encoding, or carrying instructions for execution by the machine 800 and that cause the machine 800 to perform any one or more of the techniques of the present disclosure, or that is capable of storing, encoding, or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine-readable media can include: non-volatile memory, such as semiconductor memory sub-systems (e.g., electrically programmable read-only memory (EPROM), electrically erasable programmable read-only memory (EEPROM)) and flash memory sub-systems; magnetic disks, such as internal hard disks and removable disks; magneto-optical disks; and CD-ROM and DVD-ROM disks.

In an example, information stored or otherwise provided on the machine-readable media 822 can be representative of the instructions 824, such as instructions 824 themselves or a format from which the instructions 824 can be derived. This format from which the instructions 824 can be derived can include source code, encoded instructions (e.g., in compressed or encrypted form), packaged instructions (e.g., split into multiple packages), or the like. The information representative of the instructions 824 in the machine-readable media 822 can be processed by processing circuitry into the instructions to implement any of the operations discussed herein. For example, deriving the instructions 824 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 824.

In an example, the derivation of the instructions 824 can include assembly, compilation, or interpretation of the information (e.g., by the processing circuitry) to create the instructions 824 from some intermediate or preprocessed format provided by the machine-readable media 822. The information, when provided in multiple parts, can be combined, unpacked, and modified to create the instructions 824. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, compiled, or interpreted (e.g., into a library, stand-alone executable etc.) at a local machine, and executed by the local machine.

The instructions 824 can be further transmitted or received over a communications network 826 using a transmission medium via the network interface device 820 utilizing any one of a number of transfer protocols (e.g., frame relay, internet protocol, transmission control protocol (TCP), user datagram protocol (UDP), hypertext transfer protocol (HTTP), etc.). Example communication networks can include a LAN, a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, P2P networks, among others. In an example, the network interface device 820 can include one or more physical jacks (e.g., Ethernet, coaxial, or phone jacks) or one or more antennas to connect to the network 826. In an example, the network interface device 820 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 800, and includes digital or analog communications signals or other intangible medium to facilitate communication of such software. A transmission medium is a machine-readable medium.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are. accordingly. to be regarded in an illustrative sense rather than a restrictive sense.

What is claimed is:

1. A memory system comprising:
a memory component comprising a plurality of pages; and
a processing device programmed to perform operations comprising:
issuing a first block family error avoidance (BFEA) scan on a lower page of the memory component to determine a lower page bin;
issuing a second BFEA scan on an upper page of the memory component to determine an upper page bin; and
issuing a third BFEA scan on an extra page of the memory component to determine an extra page bin.

2. The memory system of claim 1, wherein the operations further comprise:
storing data representing the lower page bin, the upper page bin, and the extra page bin in static random-access memory (SRAM).

3. The memory system of claim 2, wherein the operations further comprise:
in response to a read request from a host:
accessing the SRAM to determine the lower page bin, the upper page bin, and the extra page bin;
determining a lower page read offset voltage based on the lower page bin;
determining an upper page read offset voltage based on the upper page bin;
determining an extra page read offset voltage based on the extra page bin;
modifying a lower page read voltage using the lower page read voltage offset to generate a modified lower page read voltage;
modifying an upper page read voltage using the upper page read voltage offset to generate a modified upper page read voltage;
modifying an extra page read voltage using the extra page read voltage offset to generate a modified extra page read voltage;
using the modified page read voltages to read lower page data, upper page data, and extra page data from the memory component; and
providing the read lower page data, the upper page data, and the extra page data to the host.

4. The memory system of claim 1, wherein the operations further comprise:
periodically repeating the first BFEA scan, the second BFEA scan, and the third BFEA scan.

5. The memory system of claim 1, wherein the first BFEA scan of the lower page of the memory component scans at R1 and R5 of triple-level cell (TLC) memory cells.

6. The memory system of claim 1, wherein the second BFEA scan of the upper page of the memory component scans at R2, R4, and R6 of triple-level cell (TLC) memory cells.

7. The memory system of claim 1, wherein the third BFEA scan of the extra page of the memory component scans at R3 and R7 of triple-level cell (TLC) memory cells.

8. A method comprising:
issuing, by a processing device, a first block family error avoidance (BFEA) scan on a lower page of a memory component comprising a plurality of memory cells to determine a lower page bin;
issuing, by the processing device, a second BFEA scan on an upper page of the memory component to determine an upper page bin; and
issuing, by the processing device, a third BFEA scan on an extra page of the memory component to determine an extra page bin.

9. The method of claim 8, further comprising:
storing data representing the lower page bin, the upper page bin, and the extra page bin in static random-access memory (SRAM).

10. The method of claim 9, further comprising:
in response to a read request from a host:
accessing the SRAM to determine the lower page bin, the upper page bin, and the extra page bin;
determining a lower page read offset voltage based on the lower page bin;
determining an upper page read offset voltage based on the upper page bin;
determining an extra page read offset voltage based on the extra page bin;
modifying a lower page read voltage using the lower page read voltage offset to generate a modified lower page read voltage;
modifying an upper page read voltage using the upper page read voltage offset to generate a modified upper page read voltage;
modifying an extra page read voltage using the extra page read voltage offset to generate a modified extra page read voltage;
using the modified page read voltages to read lower page data, upper page data, and extra page data from the memory component; and
providing the read lower page data, the upper page data, and the extra page data to the host.

11. The method of claim 8, further comprising:
periodically repeating the first BFEA scan, the second BFEA scan, and the third BFEA scan.

12. The method of claim 8, wherein the first BFEA scan of the lower page of the memory component scans at R1 and R5 of triple-level cell (TLC) memory cells.

13. The method of claim 8, wherein the second BFEA scan of the upper page of the memory component scans at R2, R4, and R6 of triple-level cell (TLC) memory cells.

14. The method of claim 8, wherein the third BFEA scan of the extra page of the memory component scans at R3 and R7 of triple-level cell (TLC) memory cells.

15. A non-transitory machine-readable storage medium comprising instructions that, when executed by a processing device, cause the processing device to perform operations comprising:
issuing a first block family error avoidance (BFEA) scan on a lower page of a memory component comprising a plurality of memory cells to determine a lower page bin;
issuing a second BFEA scan on an upper page of the memory component to determine an upper page bin; and
issuing a third BFEA scan on an extra page of the memory component to determine an extra page bin.

16. The non-transitory machine-readable storage medium of claim 15, wherein the operations further comprise:
storing data representing the lower page bin, the upper page bin, and the extra page bin in static random-access memory (SRAM).

17. The non-transitory machine-readable storage medium of claim 16, wherein the operations further comprise:
in response to a read request from a host:
accessing the SRAM to determine the lower page bin, the upper page bin, and the extra page bin;
determining a lower page read offset voltage based on the lower page bin;
determining an upper page read offset voltage based on the upper page bin;
determining an extra page read offset voltage based on the extra page bin;
modifying a lower page read voltage using the lower page read voltage offset to generate a modified lower page read voltage;
modifying an upper page read voltage using the upper page read voltage offset to generate a modified upper page read voltage;
modifying an extra page read voltage using the extra page read voltage offset to generate a modified extra page read voltage;
using the modified page read voltages to read lower page data, upper page data, and extra page data from the memory component; and
providing the read lower page data, the upper page data, and the extra page data to the host.

18. The non-transitory machine-readable storage medium of claim 15, wherein the operations further comprise:
periodically repeating the first BFEA scan, the second BFEA scan, and the third BFEA scan.

19. The non-transitory machine-readable storage medium of claim 15, wherein the first BFEA scan of the lower page of the memory component scans at R1 and R5 of triple-level cell (TLC) memory cells.

20. The non-transitory machine-readable storage medium of claim 15, wherein the second BFEA scan of the upper page of the memory component scans at R2, R4, and R6 of triple-level cell (TLC) memory cells.

21. The non-transitory machine-readable storage medium of claim 15, wherein the second BFEA scan of the extra page of the memory component scans at R3 and R7 of triple-level cell (TLC) memory cells.
